(19) United States
(12) Patent Application Publication
(10) Pub. No.: US 2017/0294559 A1
(43) Pub. Date: Oct. 12, 2017

(54) SEMICONDUCTOR DEVICE

(71) Applicant: Panasonic Intellectual Property Management Co., Ltd., Osaka (JP)

(72) Inventors: Koji GOTO, Osaka (JP); Shintaro HAYASHI, Hyogo (JP); Akihiko MURAI, Osaka (JP); Takuya MINO, Osaka (JP); Saki AOKI, Osaka (JP); Kenji TSUBAKI, Osaka (JP)

(21) Appl. No.: 15/504,253

(22) PCT Filed: Nov. 4, 2015
(86) PCT No.: PCT/JP2015/005535

§ 371 Date: Feb. 15, 2017

(30) Foreign Application Priority Data
Nov. 12, 2014 (JP) 2014-230071

(51) Int. Cl. H01L 33/32; H01L 33/64

(52) U.S. Cl. CPC H01L 33/32; H01L 33/644; H01L 33/641

(57) ABSTRACT

The semiconductor device includes: an AlGaN layer; a contact electrode; an insulating film; and a passivation film. The semiconductor device further includes: an extended wire extending over the contact electrode and the insulating film; and a pad electrode electrically connected to the extended wire. The passivation film covers the insulating film and the extended wire and including an opening for exposing the pad electrode. The insulating film accommodates the opening in a plan view. The passivation film accommodates the contact electrode in a plan view. The semiconductor device further includes a heat dissipation layer on a surface of the passivation film.

### RELATED APPLICATIONS

This application is the U.S. National Phase under 35 U.S.C. §371 of International Application No. PCT/JP2015/005535, filed on Nov. 4, 2015, which in turn claims the benefit of Japanese Application No. 2014-230071, filed on Nov. 12, 2014, the disclosures of which are incorporated by reference herein.

### TECHNICAL FIELD

The present invention relates to semiconductor devices, and in particular to a semiconductor device including an AlGaN layer and a contact electrode formed on a surface of the AlGaN layer.

### BACKGROUND ART

Semiconductor devices of group-III nitride semiconductors have been researched and developed in various places. Such semiconductor devices include light emitting devices exemplified by light emitting diodes, and electronic devices exemplified by high electron mobility transistors. Recently, ultraviolet light emitting devices of group-III nitride semiconductors are greatly expected to be applied in fields of application of high efficiency white illumination, sterilization, medical procedure, high-speed processing of environmental pollutant and the like.

In the past, there has been known an ultraviolet light emitting device as one of semiconductor devices. Such an ultraviolet light emitting device includes: a laminate film which includes an n-type layer, a light emitting layer and a p-type layer and has a mesa structure; an n-electrode provided on an exposed surface of the n-type layer; and a p-electrode provided facing a surface of a p-type layer (for example, Document 1 [JP 2014-96460 A]).

In the ultraviolet light emitting device disclosed in Document 1, the n-type layer includes an n-type Al_{z}Ga_{1-z}N (0<z≦1) layer.

With regard to a semiconductor device including an AlGaN layer and a contact electrode formed on the AlGaN layer, there may be a demand to improve moisture resistance with an increase in a composition ratio of Al in the AlGaN layer. Further, there may be a demand to improve heat radiation performance of semiconductor devices.

### SUMMARY OF INVENTION

An object of the present invention would be to propose a semiconductor device having improved moisture resistance as well as improved heat radiation performance.

The semiconductor device of one aspect according to the present invention includes: an AlGaN layer; a contact electrode formed on a surface of the AlGaN layer; an insulating film formed on the surface of the AlGaN layer to surround a region of the contact electrode in contact with the AlGaN layer; and a passivation film. The semiconductor device of the aspect according to the present invention further includes: an extended wire electrically connected to the contact electrode and extending over the contact electrode and the insulating film; and a pad electrode formed on a part of the extended wire formed on the insulating film and electrically connected to the extended wire. The passivation film covers the insulating film and the extended wire and includes an opening for exposing the pad electrode. The insulating film accommodates the opening in a plan view. The passivation film accommodates the contact electrode in a plan view. The semiconductor device of the aspect according to the present invention further includes a heat dissipation layer which is formed on a surface of the passivation film and made of material having a higher heat conductivity than material of the passivation film.

### BRIEF DESCRIPTION OF DRAWINGS

FIG. 1 is a schematic section of a semiconductor device of an embodiment.

FIG. 2 is a schematic plan of a semiconductor device of an embodiment.

FIG. 3 is a schematic plan of a substrate and a mesa structure of the semiconductor device of the embodiment.

FIG. 4 is a schematic plan of the substrate and a first contact electrode of the semiconductor device of the embodiment.

FIG. 5 is a schematic plan of the substrate and a second contact electrode of the semiconductor device of the embodiment.

FIG. 6 is a schematic plan of the substrate, a first extended wire and a second extended wire of the semiconductor device of the embodiment.

FIG. 7 is a schematic plan of the substrate and a passivation film of the semiconductor device of the embodiment.

FIG. 8 is a schematic plan of the substrate, a first pad electrode, a second pad electrode and a heat dissipation layer of the semiconductor device of the embodiment.

FIG. 9 is an exemplary section of the first contact electrode of the semiconductor device of the embodiment.

FIG. 10 is an exemplary diagram of a solidification-structure of the semiconductor device of the embodiment.

### DESCRIPTION OF EMBODIMENTS

Figures mentioned in the following explanation of the embodiment are schematic, and therefore ratios of sizes or thicknesses of illustrated components may not always reflect actual ratios of dimensions. Additionally, materials, values, and the like mentioned in the explanation of the embodiment are preferable examples, and they are not used to limit the scope of the invention. Further, the embodiment embodying one aspect of the present invention may be modified in appropriate ways without departing from the scope of the technical concept of the present invention.

### Embodiment

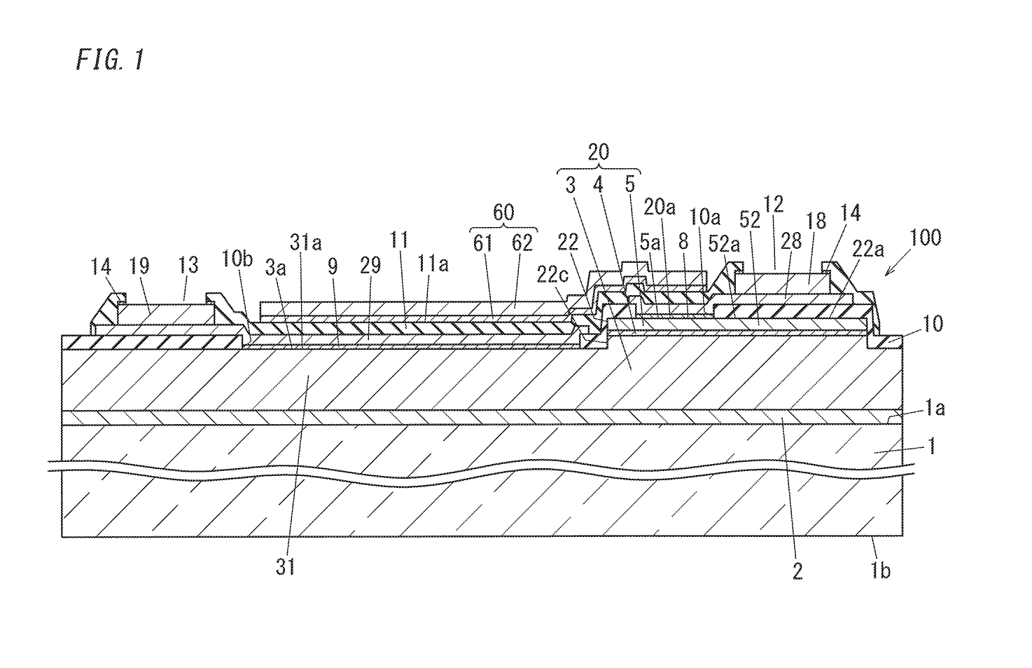

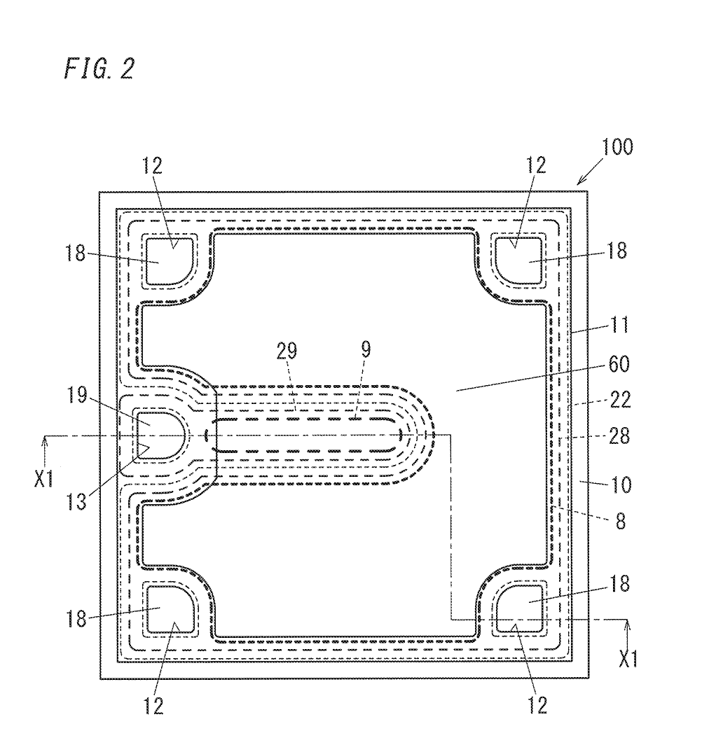

Hereinafter, a semiconductor device 100 of the present embodiment is described with reference to FIG. 1 to FIG. 10. Note that, FIG. 1 is a schematic section along XI-XI line in FIG. 2.

The semiconductor device 100 of the present embodiment is an ultraviolet light emitting device. In more detail, the semiconductor device 100 includes an n-type nitride semiconductor layer 3 including at least an AlGaN layer 31, and a p-type nitride semiconductor layer 5 including at least an AlGaN layer 52. Accordingly, the semiconductor device 100 can serve as an ultraviolet light emitting device. Preferably, the semiconductor device 100 includes a light emitting layer 4 between the n-type nitride semiconductor layer 3 and the p-type nitride semiconductor layer 5. The light emitting layer 4 may be preferably configured to emit light with an emission wavelength falling within a wavelength range of ultraviolet.

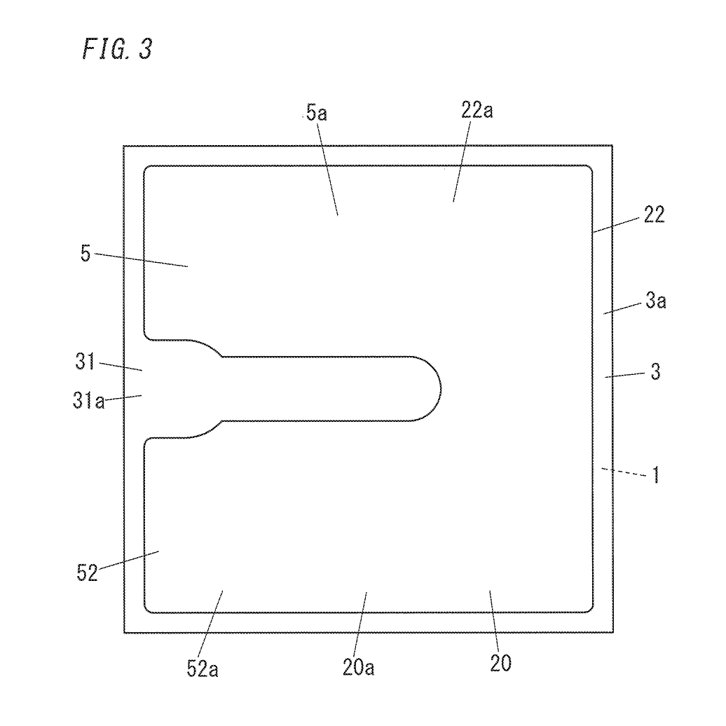

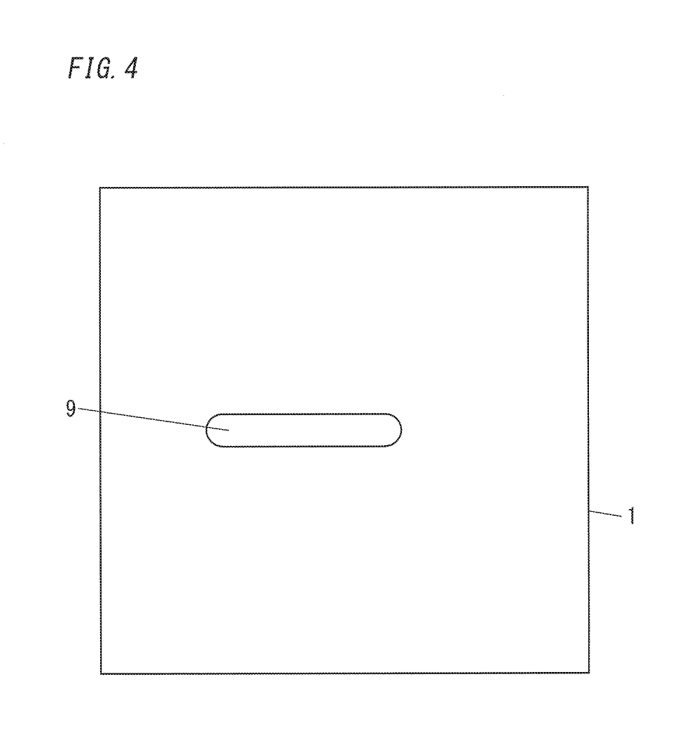

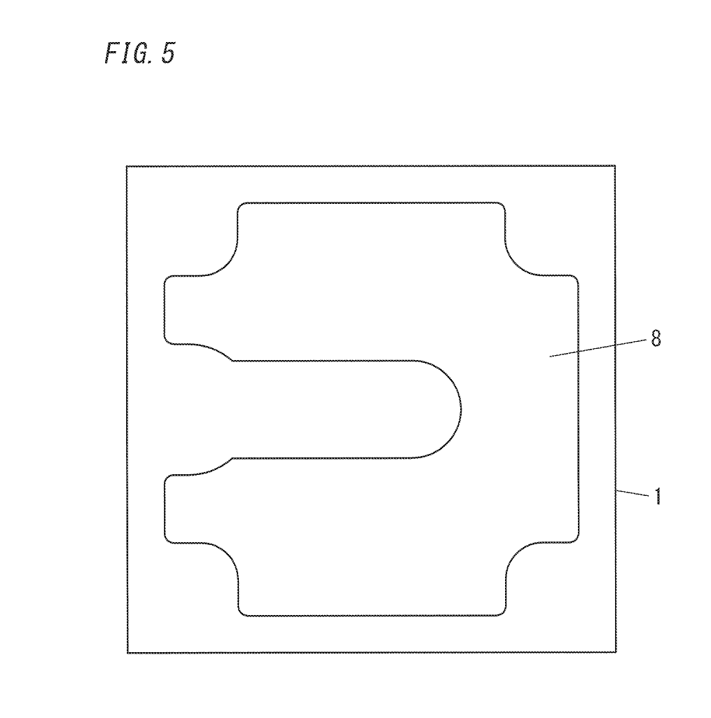

The semiconductor device 100 includes a substrate 1, and a nitride semiconductor layer which formed to face a first face 1a of the substrate 1 and includes the n-type nitride semiconductor layer 3, the light emitting layer 4 and the p-type nitride semiconductor layer 5 which are arranged in this order from the first face 1a. The light emitting layer 4 and the p-type nitride semiconductor layer 5 are smaller than the n-type nitride semiconductor layer 3 in a plan view. Further, the semiconductor device 100 includes a contact electrode 9 (see FIG. 1, FIG. 2 and FIG. 4) and a contact electrode 8 (see FIG. 1, FIG. 2 and FIG. 5). The contact electrode 9 is formed on an exposed surface 3a (see FIG. 1 and FIG. 3) of the n-type nitride semiconductor layer 3. The contact electrode 8 is formed on a surface 5a (see FIG. 1 and FIG. 3) of the p-type nitride semiconductor layer 5. The exposed surface 3a of the n-type nitride semiconductor layer 3 is a surface of the n-type nitride semiconductor layer 3 which is exposed by removing partially the nitride semiconductor layer 20 from the surface 5a of the p-type nitride semiconductor layer 5 so that the n-type nitride semiconductor layer 3 is partially removed in a depth direction thereof. In the semiconductor device 100, the exposed surface 3a of the n-type nitride semiconductor layer 3 corresponds to a surface 31a of the AlGaN layer 31, and the surface 5a of the p-type nitride semiconductor layer 5 corresponds to a surface 52a of the AlGaN layer 52.

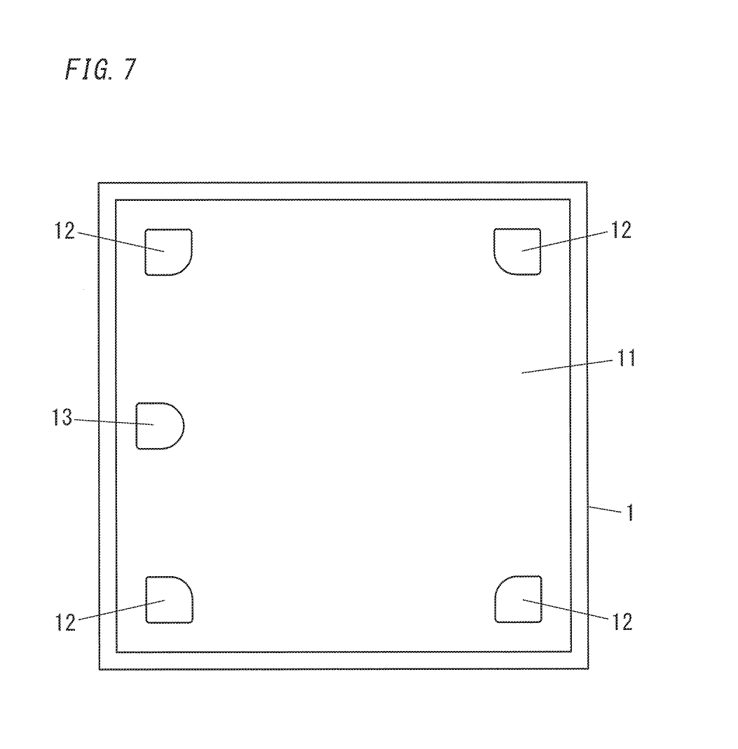

The semiconductor device 100 includes an insulating film 10 and a passivation film 11 (see FIG. 1, FIG. 2 and FIG. 7). The insulating film 10 is formed on the surface 31a of the AlGaN layer 31 to surround a region of the contact electrode 9 in contact with the AlGaN layer 31. Also, the insulating film 10 is formed on the surface 52a of the AlGaN layer 52 to surround a region of the contact electrode 9 in contact with the AlGaN layer 52.

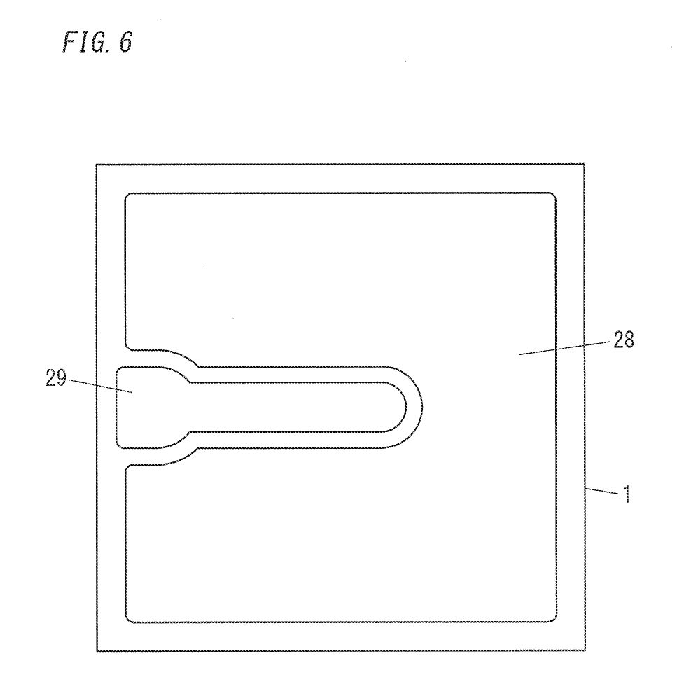

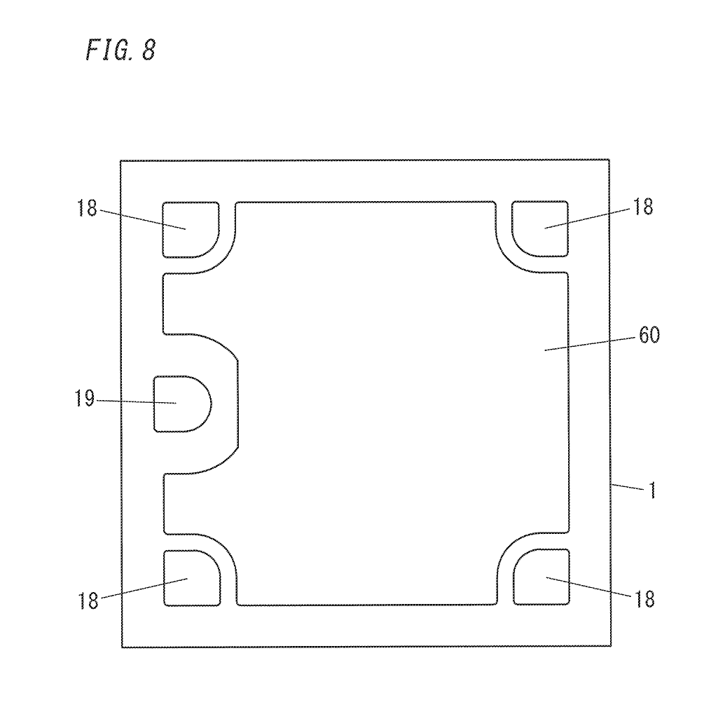

The semiconductor device 100 includes an extended wire 29 electrically connected to the contact electrode 9 and extending over the contact electrode 9 and the insulating film 10 (see FIG. 1, FIG. 2, and FIG. 6). Further, the semiconductor device 100 includes a pad electrode 19 formed on a part of the extended wire 29 formed on the insulating film 10 and electrically connected to the extended wire 29 (see FIG. 1, FIG. 2, and FIG. 8). Moreover, the semiconductor device 100 includes an extended wire 28 electrically connected to the contact electrode 8 and extending over the contact electrode 8 and the insulating film 10 (see FIG. 1, FIG. 2, and FIG. 5). Further, the semiconductor device 100 includes pad electrodes 18 formed on parts of the extended wire 28 formed on the insulating film 10 and electrically connected to the extended wire 28.

The passivation film 11 covers the insulating film 10 and the extended wire 29 and 28, and includes openings 13 and 12 respectively exposing the pad electrodes 19 and 18. The insulating film 10 accommodates the openings 13 and 12 in a plan view. The passivation film 11 accommodates the contact electrodes 9 and 8 in a plan view. The expression “the passivation film 11 accommodates the contact electrodes 9 and 8 in a plan view” means that the contact electrodes 9 and 8 are positioned inside a vertical projection region of the passivation film 11 with regard to a projection direction is parallel to a thickness direction of the AlGaN layer 31, that is a vertical projection region of the passivation film 11 on a plane perpendicular to the thickness direction of the AlGaN layer 31.

The semiconductor device 100 includes a heat dissipation layer 60 which is formed on a surface 11a of the passivation film 11 and made of material having a higher heat conductivity than material of the passivation film 11.

In the semiconductor device 100, the nitride semiconductor layer 20 is formed to face the first face 1a of the substrate 1, as described above. In the semiconductor device 100, a second face 1b on an opposite side of the substrate 1 from the first face 1a may preferably serve as a light exit surface.

The semiconductor device 100 has a chip size of 400 μm □ (400 μm×400 μm). However, the chip size is not limited to this value. In a case of the semiconductor device 100 serving as an ultraviolet light emitting device, the chip size may be appropriately set to be in a range of about 200 μm □ (200 μm×200 μm) to about 1 mm □ (1 mm×1 mm), for example. Moreover, a plan shape of the semiconductor device 100 is not limited to a square shape, but may be a rectangular shape or the like.

Hereinafter, components of the semiconductor device 100 are described in detail.

The semiconductor device 100 can serve as an ultraviolet light emitting diode having an emission wavelength (emission peak wavelength) within an ultraviolet wavelength range of, for example, 210 nm to 280 nm. In this case, for example, the semiconductor device 100 can be used in fields of application of high efficiency white illumination, sterilization, medical procedure, high-speed processing of environmental pollutant and the like. In a case of ultraviolet light emitting devices such as ultraviolet light emitting diodes, the semiconductor device 100 may be preferably configured to emit light with an emission wavelength in a wavelength range of UV-C. The wavelength range of UV-C ranges from 100 nm to 280 nm based on classification of wavelength of ultraviolet light designated by the International Commission on Illumination (CIE). The term “emission peak wavelength” means a main emission peak wavelength at a room temperature (27° C.).

The substrate 1 may be a sapphire substrate having a (0001) plane serving as the first face 1a, for example. In other words, the substrate 1 may be made of a c-plane sapphire substrate (α-Al₂O₃ substrate). Note that, the sapphire substrate has an off angle relative to the (0001) plane may be preferably in a range of 0 to 0.4°.

The semiconductor device 100 may preferably include a buffer layer 2 between the substrate 1 and the n-type nitride semiconductor layer 3. In summary, in the semiconductor device 100, it is preferable that the buffer layer 2 be formed on the first face 1a of the substrate 1 and the n-type nitride semiconductor layer 3 be formed on the buffer layer 2. The buffer layer 2 may be an Al_{y}Ga_{1-y}yN (0≦y≦1) layer. The buffer layer 2 may be preferably an AlN layer.

The buffer layer 2 is provided for the purpose of reducing threading dislocations. If the buffer layer 2 is too thin, a decrease in threading dislocations may be insufficient. In contrast, if the buffer layer 2 is too thick, cracks may be caused due to lattice mismatch, and a wafer for forming a plurality of semiconductor devices 100 may show excess warp. In view of this, the thickness of the buffer layer 2 may be preferably in a range of about 500 nm to 10 μm, may be more preferably in a range of 1 μm to 5 μm. For example, the buffer layer 2 has a thickness of 4 μm.

The n-type nitride semiconductor layer 3 may be formed of, for example, an n-type AlGaN layer 31. The n-type AlGaN layer 31 forming the n-type nitride semiconductor layer 3 has a composition ratio which may be preferably selected so as to allow efficient emission of ultraviolet light produced in the light emitting layer 4. For example, the light emitting layer 4 has a quantum well structure including a barrier layer and a well layer, and the well layer has an Al composition ratio of 0.5, and the barrier layer has an Al composition ratio of 0.7. In this case, the n-type AlGaN layer 31 may have an Al composition ratio of 0.7 which is equal to the Al composition ratio of the barrier layer. In summary, the well layer and the barrier layer of the light emitting layer 4 are formed of an Al_{0.5}Ga_{0.5}N layer and an Al_{0.7}Ga_{0.3}N layer, respectively, the n-type nitride semiconductor layer 3 may be formed of an n-type Al_{0.7}Ga_{0.3}N layer, for example. The Al composition ratio of the n-type nitride semiconductor layer 3 may be equal to or different from the Al composition ratio of the barrier layer. Further, the n-type nitride semiconductor layer 3 is not limited to a single layer film, but may be a laminated film which is a stack of multiple n-type AlGaN layers with different Al composition ratios with a topmost n-type AlGaN layer being the AlGaN layer 31. The n-type nitride semiconductor layer 3 may have a thickness of 2 μm, for example. Donor impurities for the n-type nitride semiconductor layer 3 may preferably be Si, for example. Additionally, the n-type nitride semiconductor layer 3 may have an electron concentration ranging from about 1×10¹⁸ to 1×10¹⁹ cm⁻³.

The light emitting layer 4 is for converting injected carriers (in this embodiment, electrons and holes) into light. In other words, the light emitting layer 4 is for emitting ultraviolet light by recombination of injected two types of carriers (electrons and holes). The light emitting layer 4 may preferably include a quantum well structure. In the light emitting layer 4, the well layer of the quantum well structure may preferably be formed of an AlₐGa₁₋ₐN (0<a<1) layer, and the barrier layer of the quantum well structure may preferably be formed of an Al_{b}Ga_{1-b}N (0<b≦1, b>a) layer. The emission wavelength of the light emitting layer 4 including the well layer formed of an AlₐGa₁₋ₐN (0<a<1) layer can be selected from a range of 210 nm to 360 nm, by adjusting an Al composition ratio “a” of the well layer. For example, when a desired emission wavelength is about 265 nm, the Al composition ratio “a” may be adjusted to 0.50. In the light emitting layer 4, the well layer of the quantum well structure may be formed of an InAlGaN layer.

The quantum well structure may be a multiquantum well structure or a single quantum well structure. If the light emitting layer 4 has the well layer too thick, it may be considered that electrons and holes injected into the well layer may be spatially separated due to a piezoelectric field caused by lattice mismatch in the quantum well structure and this may cause a decrease in light emission efficiency. In contrast, if the light emitting layer 4 has the well layer too thin, it may be considered that this may cause a decrease in effects of carrier confinement, leading to a decrease in light emission efficiency. For this reason, for example, the thickness of the well layer may be preferably in a range of 1 nm to 5 nm, and be more preferably in a range of about 1.3 nm to 3 nm. Further, the thickness of the barrier layer may range from about 5 nm to 15 nm, for example. For example, in the semiconductor device 100, the well layer has a thickness of 2 nm and the barrier layer has a thickness of 10 nm. The semiconductor device 100 may not be limited to a structure where the light emitting layer 4 has a quantum well structure, but may have a double heterostructure in which a single layer serving as the light emitting layer 4 is between the n-type nitride semiconductor layer 3 and the p-type nitride semiconductor layer 5. Alternatively, the semiconductor device 100 may not include the light emitting layer 4, but may include a pn-junction of the n-type nitride semiconductor layer 3 and the p-type nitride semiconductor layer 5.

The p-type nitride semiconductor layer 5 may be formed of, for example, a p-type AlGaN layer 52. The p-type AlGaN layer 52 may be preferably formed of a p-type Al_{d}Ga_{1-d}N (0<d<1) layer. The p-type Al_{d}Ga_{1-d}N (0<d<1) layer has a composition ratio which may be preferably selected so as to suppress absorption of ultraviolet light produced in the light emitting layer 4. For example, in the light emitting layer 4, the well layer has an Al composition ratio of 0.5, and the barrier layer has an Al composition ratio “b” of 0.7. In this case, the p-type Al_{d}Ga_{1-d}N (0<d<1) layer may have an Al composition ratio “d” which is equal to 0.7 which is equal to the Al composition ratio “b” of the barrier layer. In summary, the well layer of the light emitting layer 4 is formed of an Al_{0.5}Ga_{0.5}N layer, the p-type AlGaN layer 52 may be formed of a p-type Al_{0.7}Ga_{0.3}N layer, for example. The Al composition ratio of the p-type AlGaN layer 52 may be equal to or different from the Al composition ratio “b” of the barrier layer. The p-type nitride semiconductor layer 5 may have a thickness of 300 nm, for example. Acceptor impurities for the p-type nitride semiconductor layer 5 may preferably be Mg, for example.

The p-type nitride semiconductor layer 5 is not limited to a single layer film, but may be a laminated film which is a stack of, for example, an electron block layer formed of a p-type Al_{c}Ga_{1-c}N (0<c<1) layer, a p-type Al_{d}Ga_{1-d}N (0<d<1) layer, and a p-type AlGaN layer 52.

The p-type Al_{c}Ga_{1-c}N (0<c<1) layer may be provided as an electron block layer for suppressing leakage (overflow), to the p-type Al_{d}Ga_{1-d}N (0<d<1) layer, of electrons which are some of electrons injected into the light emitting layer 4 but are not recombined with holes inside the light emitting layer 4. The Al composition ratio “c” of the p-type Al_{c}Ga_{1-c}N (0<c<1) layer may be, for example, 0.9. The composition ratio of the p-type Al_{c}Ga_{1-c}N (0<c<1) layer may be preferably set so that a bandgap energy of the electron block layer is higher than a bandgap energy of the p-type Al_{d}Ga_{1-d}N (0<d<1) layer or the barrier layer. The thickness of the electron block layer may be preferably in a range of, for example, 1 nm to 50 nm, and more preferably in a range of 5 nm to 25 nm. Acceptor impurities for the electron block layer may be, for example, Mg.

The p-type Al_{d}Ga_{1-d}N (0<d<1) layer is for transporting holes to the light emitting layer 4. The p-type Al_{d}Ga_{1-d}N (0<d<1) layer may preferably have a composition ratio adjusted to suppress absorption of ultraviolet light produced in the light emitting layer 4. For example, when in the light emitting layer 4 the well layer has the Al composition ratio of 0.5 and the barrier layer has the Al composition ratio “b” of 0.7, the p-type Al_{d}Ga_{1-d}N (0<d<1) layer may have the Al composition ratio “d” which is equal to 0.7 which is equal to, for example, the Al composition ratio “b” of the barrier layer. In summary, when the well layer of the light emitting layer 4 is formed of an Al_{0.5}Ga_{0.5}N layer, the p-type Al_{d}Ga_{1-d}N (0<d<1) layer may be, for example, formed of the p-type Al_{0.7}Ga_{0.3}N layer. The p-type Al_{d}Ga_{1-d}N (0<d<1) layer may have an Al composition ratio which is equal to or different from the Al composition ratio “b” of the barrier layer. Acceptor impurities for the p-type Al_{d}Ga_{1-d}N (0<d<1) layer may preferably be, for example, Mg.

The p-type AlGaN layer 52 on the p-type Al_{d}Ga_{1-d}N (0<d<1) layer may be provided as a contact layer for reducing contact resistance with the contact electrode 8 to achieve fine ohmic contact with the contact electrode 8. The p-type AlGaN layer 52 may preferably have a higher hole concentration than the p-type Al_{d}Ga_{1-d}N (0<d<1) layer.

The semiconductor device 100 may be designed so that the nitride semiconductor layer includes the buffer layer 2, the n-type nitride semiconductor layer 3, the light emitting layer 4 and the p-type nitride semiconductor layer 5, as described above. The nitride semiconductor layer 20 may not include the buffer layer 2 and the light emitting layer 4. The nitride semiconductor layer 20 may be formed by epitaxial growth. Examples of epitaxial growth may include, for example, MOVPE (metal organic vapor phase epitaxy), HVPE (hydride vapor phase epitaxy), and MBE (molecular beam epitaxy). Note that, the nitride semiconductor layer 20 may contain unavoidable impurities such as H, C, O, Si, and Fe resulting from formation of the nitride semiconductor layer 20.

In the semiconductor device 100, the nitride semiconductor layer 20 is partially removed by etching the nitride semiconductor layer 20 from its surface 20a until reaching an almost middle of the n-type nitride semiconductor layer 3. Thereby, the semiconductor device 100 has the surface 3a of the n-type nitride semiconductor layer 3 exposed. In summary, the semiconductor device 100 has a mesa structure 22 (see FIG. 1 to FIG. 3) which is formed by etching the nitride semiconductor layer 20 partially. In the semiconductor device 100, the contact electrode 9 (hereinafter, also referred to as “first contact electrode 9”) is formed on the surface 3a of the n-type nitride semiconductor layer 3, and the contact electrode 8 (hereinafter also referred to as “second contact electrode 8”) is formed on the surface 5a of the p-type nitride semiconductor layer 5. In the semiconductor device 100, the surface 5a of the p-type nitride semiconductor layer 5 serves as the surface 20a of the nitride semiconductor layer 20.

The first contact electrode 9 is electrically connected to the n-type nitride semiconductor layer 3. The first contact electrode 9 may preferably have a shape with its section of which an area becomes gradually smaller with an increase in a distance from the n-type nitride semiconductor layer 3 along a thickness direction of the n-type nitride semiconductor layer 3. In more detail, the first contact electrode 9 may preferably have a shape with its section of which an area becomes gradually smaller with an increase in the distance from the n-type nitride semiconductor layer 3 along the thickness direction of the n-type nitride semiconductor layer 3, by tapering side faces thereof.

The first contact electrode 9 serves as an electrode for achieving ohmic contact with the n-type nitride semiconductor layer 3. For example, the first contact electrode 9 may be formed by steps of: forming a laminated film of a first Al film, a first Ni film, a second Al film, a second Ni film, and an Au film on the surface 3a of the n-type nitride semiconductor layer 3; annealing the same; and slowly cooling the same. As for the laminated film, each of the first Al film, the first Ni film, the second Al film, the second Ni film and the Au film has a thickness in a range of 10 to 200 nm.

The first contact electrode 9 may be formed of a solidification structure containing Ni and Al as its main components. Therefore, the semiconductor device 100 can have a contact resistance between the n-type nitride semiconductor layer 3 and the first contact electrode 9 reduced. The solidification structure means a crystalline structure resulting from solidification of molten metal. In other words, such a solidification structure can be considered a molten solidification structure formed by solidification of molten metal containing Ni and Al. The solidification structure containing Ni and Al as its main components may contain Au and N as impurities, for example.

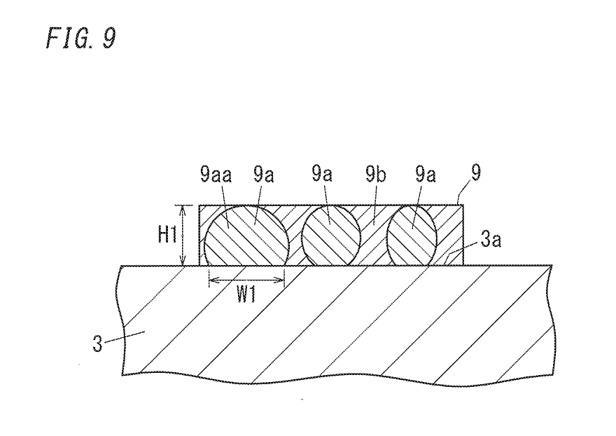

As shown in FIG. 9, the solidification structure has a mixture of multiple Ni primary crystals 9a in contact with the surface 3a of the n-type nitride semiconductor layer 3 and an AlNi eutectic 9b in contact with the surface 3a of the n-type nitride semiconductor layer 3. Therefore, the semiconductor device 100 can have the contact resistance between the n-type nitride semiconductor layer 3 and the first contact electrode 9 reduced, and also have a sheet resistance of the first contact electrode 9 reduced. The AlNi eutectic 9b has the Al composition ratio ranging from about 96 to 97 at %, and therefore is an Al-rich structure richer in Al than Ni. As for the solidification structure forming the first contact electrode 9, the multiple Ni primary crystals 9a may be considered to contribute mainly to a decrease in the contact resistance, and the AlNi eutectic 9b may be considered to contribute mainly to a decrease in the sheet resistance. The Ni primary crystals 9a may preferably contain Au and N as impurities, for example. A reason why the Ni primary crystals 9a contain N as impurities can be explained by a putative mechanism in which N derived from the n-type nitride semiconductor layer 3 forms solid solution in crystalline growth of the Ni primary crystals 9a. The AlNi eutectic 9b may contain Au as impurities, for example. The semiconductor device 100 can be made based on a different putative mechanism.

The multiple Ni primary crystals 9a of the first contact electrode 9 may preferably include an Ni primary crystal 9aa (see FIG. 9) which satisfies the following requirement.

Requirement: extending an entire length in the thickness direction of the first contact electrode 9, and having a continuous region in contact with the n-type nitride semiconductor layer 3 which has a dimension W1 (see FIG. 9) in a direction in a plane of the first contact electrode 9 larger than a thickness H1 (see FIG. 9) of the first contact electrode 9.

Accordingly, the semiconductor device 100 can have the contact resistance between the Ni primary crystal 9a and the surface 3a of the n-type nitride semiconductor layer 3 more reduced.

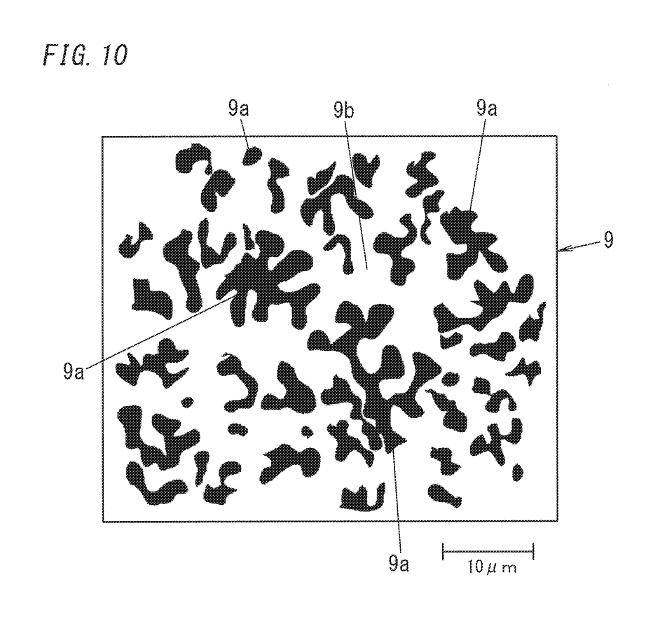

The Ni primary crystal 9a may preferably be a dendritic crystal and have a dendritic section perpendicular to the thickness direction of the n-type nitride semiconductor layer 3. Accordingly, the semiconductor device 100 can have a contact area between the Ni primary crystals 9a and the surface 3a of the n-type nitride semiconductor layer 3 increased, and also can have the contact resistance more reduced. Note that, the section of the Ni primary crystals 9a perpendicular to the thickness direction the n-type nitride semiconductor layer 3 is almost the same as a dendritic shape schematically shown in FIG. 10.

The semiconductor device 100 can have the contact resistance between the n-type nitride semiconductor layer 3 and the first contact electrode 9 reduced, thereby decreasing an operation voltage of the semiconductor device 100 and improving luminance.

Note that, forming the first contact electrode 9 to contain Ni and Al as main components as described above may be merely one example. The first contact electrode 9 may be made of a different material containing Ti and/or the like.

In the semiconductor device 100, the n-type nitride semiconductor layer 3 and the first contact electrode 9 may preferably be in ohmic contact with each other. In the case of the contact between the n-type nitride semiconductor layer 3 and the first contact electrode 9, the ohmic contact means an electrical junction which does not rectify a current resulting from application of voltage in any direction. The ohmic contact may preferably have an almost linear current voltage curve and more preferably a linear current voltage curve. Further, the ohmic contact may preferably have a lower contact resistance. As for the contact between the n-type nitride semiconductor layer 3 and the first contact electrode 9, a current flowing through an interface between the n-type nitride semiconductor layer 3 and the first contact electrode 9 can be considered a sum of a thermionic electron emission current flowing over a schottky barrier and a tunnel current flowing through the schottky barrier. Hence, as for the contact between the n-type nitride semiconductor layer 3 and the first contact electrode 9, it may be considered that the ohmic contact is nearly achieved providing that the tunnel current is dominant.

The second contact electrode 8 is electrically connected to the p-type nitride semiconductor layer 5. In more detail, the second contact electrode 8 is electrically connected to the p-type AlGaN layer 52.

The second contact electrode 8 may preferably have a shape with its section of which an area becomes gradually smaller with an increase in a distance from the p-type nitride semiconductor layer 5 along a thickness direction of the p-type nitride semiconductor layer 5. In more detail, the second contact electrode 8 may preferably have a shape with its section of which an area becomes gradually smaller with an increase in the distance from the p-type nitride semiconductor layer 5 along the thickness direction of the p-type nitride semiconductor layer 5, by tapering side faces thereof.

The second contact electrode 8 serves as an electrode for achieving ohmic contact with the p-type nitride semiconductor layer 5. For example, the second contact electrode 8 may be formed in a similar manner to the first contact electrode 9. In brief, the second contact electrode 8 may be formed by steps of: forming a stack of an Al film, an Ni film, and an Au film on the surface 5a of the p-type nitride semiconductor layer 5; annealing the same; and slowly cooling the same.

The insulating film 10 may be preferably formed to extend over part of the upper face 22a of the mesa structure 22 (the surface 20a of the nitride semiconductor layer 20), the side face 22c of the mesa structure 22, and part of the surface 3a of the n-type nitride semiconductor layer 3. The insulating film 10 is a film with electrically insulating properties. Examples of material of the insulating film 10 may include SiO₂. In summary, the insulating film 10 may preferably be made of a silicon oxide film. Examples of material of the insulating film 10 may include Si₃N₄, Al₂O₃, TiO₂, Ta₂O₅, ZrO₂, Y₂O₃, CeO₂, and Nb₂O₅ in addition to SiO₂. The insulating film 10 may have a thickness of 1 μm. Examples of methods of forming the insulating film 10 may include, for example, CVD (chemical vapor deposition), evaporation, and sputtering. The insulating film 10 may be a single layer film or a multilayered film. The multilayered film serving as the insulating film 10 may be a dielectric multilayered film for reflecting light (ultraviolet light) produced by the light emitting layer 4.

The insulating film 10 includes a contact hole 10b (hereinafter, also referred to as “first contact hole 10b”) for exposing the first contact electrode 9 and a contact hole 10a (hereinafter, also referred to as “second contact hole 10a”) for exposing the second contact electrode 8.

The first contact hole 10b may preferably have a shape with its opening area becomes gradually larger with an increase in the distance from the n-type nitride semiconductor layer 3 along the thickness direction of the n-type nitride semiconductor layer 3. In more detail, the first contact hole 10b may preferably have a shape with its opening area becomes gradually larger with an increase in the distance from the n-type nitride semiconductor layer 3 along the thickness direction of the n-type nitride semiconductor layer 3, by tapering internal side faces thereof. In the semiconductor device 100, the internal side faces of the first contact hole 10b may be separate from the side faces of the first contact electrode 9.

The second contact hole 10a may preferably have a shape with its opening area becomes gradually larger with an increase in a distance from the p-type nitride semiconductor layer 5 along the thickness direction of the p-type nitride semiconductor layer 5. In more detail, the second contact hole 10a may preferably have a shape with its opening area becomes gradually larger with an increase in the distance from the p-type nitride semiconductor layer 5 along the thickness direction of the p-type nitride semiconductor layer 5, by tapering internal side faces thereof. In the semiconductor device 100, the internal side faces of the second contact hole 10a may be separate from the side faces of the second contact electrode 8.

The extended wire 29 (hereinafter also referred to as “first extended wire 29”) is formed to extend over the first contact electrode 9 and the insulating film 10. In more detail, the first extended wire 29 is formed to extend over a surface of the first contact electrode 9 and a surface of part of the insulating film 10 which is formed on the surface 3a of the n-type nitride semiconductor layer 3. The first extended wire 29 (see FIG. 1, FIG. 2 and FIG. 6) may preferably be formed to be smaller than the surface 3a (see FIG. 1, and FIG. 3) of the n-type nitride semiconductor layer 3 in a plan view. The first extended wire 29 covers the surface 3a of the n-type nitride semiconductor layer 3 in a planar manner in a plan view.

The first extended wire 29 may preferably be made of metal which is relatively lower in resistivity of various metals. The first extended wire 29 may be made of a laminated film of, for example, a Ti layer and an Au layer. The first extended wire 29 may not be limited to such a laminated film of a Ti layer and an Au layer, but may be a layer of an alloy such as an aluminum alloy. Examples of the aluminum alloy may include AlSi, AlSiCu, AlCu, AlSb, and AlTiCu, for example. The first extended wire 29 may have a thickness of 250 nm, for example.

The extended wire 28 (hereinafter also referred to as “second extended wire 28”) is formed to extend over the second contact electrode 8 and the insulating film 10. In more detail, the second extended wire 28 is formed to extend over a surface of the second contact electrode 8 and a surface of part of the insulating film 10 which is formed on the surface 5a of the p-type nitride semiconductor layer 5. The second extended wire 28 may preferably be formed to be smaller than the p-type nitride semiconductor layer 5 in a plan view. The second extended wire 28 covers the p-type nitride semiconductor layer 5 in a planar manner in a plan view. The phrase “covering the p-type nitride semiconductor layer 5 in a planar manner in a plan view” means that covering an almost entire surface 5a of the p-type nitride semiconductor layer 5 in a plan view. The second extended wire 28 shown in FIG. 1 and FIG. 2 covers an entire region which is slightly smaller than the entire surface 5a of the p-type nitride semiconductor layer 5 in a plan view. In more detail, the second extended wire 28 is positioned to be separate from an outer periphery of the p-type nitride semiconductor layer 5 by a prescribed distance, in a plan view.

The second extended wire 28 may preferably be made of metal which is relatively lower in resistivity of various metals. The second extended wire 28 may be made of a laminated film of, for example, a Ti layer and an Au layer. The second extended wire 28 may be preferably made of the same material as the first extended wire 29. The second extended wire 28 may have a thickness of 250 nm, for example. The second extended wire 28 may not be limited to a multilayered structure but may be a single layer structure.

The semiconductor device 100 has the first extended wire 29 and the second extended wire 28 positioned such that the first extended wire 29 and the second extended wire 28 do not overlap with each other in a plan view. The sentence “the first extended wire 29 and the second extended wire 28 do not overlap with each other in a plan view” means that the first extended wire 29 and the second extended wire 28 do not overlap with each other but separate from each other when viewed in a direction along the thickness direction of the p-type nitride semiconductor layer 5.

The pad electrode 19 (hereinafter also referred to as “first pad electrode 19”) serves as an electrode for connecting with external devices. In other words, the first pad electrode 19 serves as a mounting electrode. In more detail, in mounting the semiconductor device 100 to a package, a wiring board, or the like, electrically conductive wire, electrically conductive bump, or the like may be bonded to the first pad electrode 19. The first pad electrode 19 may be preferably made of an Au layer. The Au layer for forming the first pad electrode 19 may have a thickness of 1300 nm, for example. As shown in FIG. 2, in the semiconductor device 100, one first contact electrode 9 is electrically connected to one first pad electrode 19.

Each pad electrode 18 (hereinafter also referred to as “second pad electrode 18”) serves as an electrode for connecting with external devices. In other words, the second pad electrodes 18 serve as mounting electrodes. In more detail, in mounting the semiconductor device 100 to a package, a wiring board, or the like, electrically conductive wire, electrically conductive bump, or the like may be bonded to each second pad electrodes 18. Examples of the electrically conductive wire may include, for example, an Au wire. Examples of the electrically conductive bump may include, for example, an Au bump. The second pad electrode 18 may have a single layer structure or a multilayered structure, but when having a multilayered structure includes an Au layer as a layer to be connected to external devices. The Au layer, to be connected to external devices, of the second pad electrode 18 may have a thickness of 1300 nm, for example. As shown in FIG. 2, in the semiconductor device 100, one second contact electrode 8 is electrically connected to four second pad electrodes 18.

The first pad electrode 19 and the second pad electrode 18 may preferably have tapered side faces. Thus, the semiconductor device 100 can have an improved step coverage of the passivation film 11.

The passivation film 11 may preferably cover the insulating film 10, the first extended wire 29, the second extended wire 28, a periphery of the first pad electrode 19, and peripheries of the second pad electrodes 18. In this case, the opening 13 (hereinafter also referred to as “first opening 13”) for exposing the first pad electrode 19 exposes a central part of the first pad electrode 19 (a central part of the surface of the first pad electrode 19). Further, the openings 12 (hereinafter also referred to as “second openings 12”) for exposing the second pad electrodes 18 expose central parts of the second pad electrodes 18 (central parts of the surfaces of the second pad electrodes 18), individually. In the semiconductor device 100, the passivation film 11 may not cover the periphery of the first pad electrode 19 and the peripheries of the second pad electrodes 18, and the first opening 13 may expose the entire first pad electrode 19 and the second opening 12 may expose the entire second pad electrodes 18. Note that, in the semiconductor device 100, the passivation film 11 may not cover the entire region of part of the surface of the first extended wire 29 which is not covered with the first pad electrode 19, and the first opening 13 may expose part of the first extended wire 29 near the first pad electrodes 19. Additionally, in the semiconductor device 100, the passivation film 11 may not cover the entire region of part of the surface of the second extended wire 28 which is not covered with the second pad electrodes 18, and the second openings 12 may expose parts of the extended wire 28 near the second pad electrodes 18.

The first opening 13 may preferably have a shape with its opening area becomes gradually larger with an increase in the distance from the n-type nitride semiconductor layer 3 along the thickness direction of the n-type nitride semiconductor layer 3, by tapering internal side faces thereof.

Each second opening 12 may preferably have a shape with its opening area becomes gradually larger with an increase in the distance from the p-type nitride semiconductor layer 5 along the thickness direction of the p-type nitride semiconductor layer 5, by tapering internal side faces thereof. The passivation film 11 includes the second openings 12 individually corresponding to the four second pad electrodes 18.

The aforementioned insulating film 10 accommodates the first opening 13 and the second openings 12 in a plan view. The expression “the insulating film 10 accommodates the first opening 13 and the second openings 12 in a plan view” means that the first opening 13 and the second openings 12 are positioned inside a vertical projection region of the insulating film 10 with regard to a projection direction is parallel to the thickness direction of the AlGaN layer 31, that is a vertical projection region of the insulating film 10 on a plane perpendicular to the thickness direction of the AlGaN layer 31.

The passivation film 11 may be preferably made of, for example, a silicon nitride film. Accordingly, the passivation film 11 can have lower moisture permeability than a silicon oxide film, and thus the moisture resistance can be improved. The passivation film 11 has electrically insulating properties. The passivation film 11 may be preferably formed by a plasma CVD. Accordingly, the semiconductor device 100 can have the step coverage of the passivation film 11 and the density of the passivation film 11 improved in this case more than in a case where the passivation film 11 is made by evaporation or sputtering. As to the semiconductor device 100, in a case of forming the passivation film 11 by a plasma CVD, the passivation film 11 can be formed at a temperature sufficiently lower than melting points of materials exemplifying the materials of the first extended wire 29 and the second extended wire 28.

The semiconductor device 100 may preferably include an adhesive layer 14 between the passivation film 11 and the periphery of the first pad electrode 19. Additionally, the semiconductor device 100 includes adhesive layers 14 individually between the passivation film 11 and the peripheries of the second pad electrodes 18.

The adhesive layer 14 is more adhesive to the passivation film 11 than the first pad electrode 19 and the second pad electrode 18 are. The adhesive layer 14 may be preferably made of one material selected from a group consisting of Ti, Cr, Nb, Zr, TiN, and TaN.

The heat dissipation layer 60 may preferably cover an almost entire surface 11a of the passivation film 11. The phrase “almost entire surface 11a of the passivation film 11” may not be limited to the entire surface 11a. The phrase “almost entire surface 11a of the passivation film 11” may mean the entire surface except for a periphery of the first opening 13 and peripheries of the second openings 12 of the passivation film 11. In brief, the heat dissipation layer 60 may preferably cover the surface 11a of the passivation film 11 in a planar manner. Thus, the semiconductor device 100 can have a more improved heat radiation performance.

The heat dissipation layer 60 may include, for example, a first layer 61 formed on the surface 11a of the passivation film 11, and a second layer 62 formed on the first layer 61. In this case, it may be preferable that the heat dissipation layer 60 may be preferably formed so that the second layer 62 is an Au layer and the material of the first layer 61 is one selected from a group consisting of Ti, Cr, Nb, Zr, TiN, and TaN.

The following detailed description is made to one example of a method of manufacturing the semiconductor device 100.

(1) Step of Preparing a Wafer

A wafer is a circular substrate. When the substrate 1 of the semiconductor device 100 is to be made of a sapphire substrate, the wafer may be a sapphire wafer. The wafer may be preferably provided with an orientation flat. The wafer may preferably have a thickness in a range of several hundred μm to several mm, and more preferably have a thickness in a range of 200 μm to 1 mm. The wafer may preferably have a diameter in a range of, for example, 50.8 mm to 150 mm.

The wafer may preferably satisfy or conform to standards designated by Japan Electronic Industry Development Association (JEIDA), SEMI (Semiconductor Equipment and Materials International), or the like. The sapphire wafer may preferably satisfy or conform to specifications for sapphire substrate to use for compound semiconductor epitaxial wafers standardized in SEMI M65-0306, for example. Note that, in the sapphire wafer, a first plane corresponds to the first face 1a of the substrate 1. Examples of the first plane of the sapphire substrate may include a c-plane, an m-plane, an a-plane, and an R-plane, and a (0001) plane being a c-plane is preferable. Additionally, an off angle of the first plane of the sapphire wafer relative to the (0001) plane may preferably in a range of 0 to 0.4°.

(2) Process of Forming the Nitride Semiconductor Layer 20 on/Over the First Plane of the Wafer

In this process, the nitride semiconductor layer 20 is formed by epitaxial growth.

In this process, MOVPE is used as epitaxial growth for forming the nitride semiconductor layer 20. In this process, MOVPE may be preferably low pressure MOVPE.

As a source gas of Al, trimethylaluminium (TMAl) may be preferably used. As a source gas of Ga, trimethylgallium (TMGa) may be preferably used. As a source gas of N, NH₃ may be preferably used. As a source gas of Si being impurities contributing to n-type conductivity, tetraethyl silane (TESi) may be preferably used. As a source gas of Mg being impurities contributing to p-type conductivity, bis(cyclopentadienyl)magnesium (Cp₂Mg) may be preferably used. As carrier gases for the above source gases, an H₂ gas may be preferably used, for example.

The source gasses are not limited particularly. For example, tryethylgallium (TEGa), a hydrazine derivative, and mono silane (SiH₄) may be used as the source gases of Ga, N, and Si, respectively.

As for growth conditions of the nitride semiconductor layer 20, a substrate temperature, a V/III ratio, supply amounts of the source gasses, growth pressure, and the like may be appropriately adjusted.

Examples of the epitaxial growth for forming the nitride semiconductor layer 20 may include MBE and HVPE in addition to MOVPE.

(3) Process of Annealing in Order to Activate the p-Type Impurities

This process includes keeping a temperature inside an annealing oven of annealing apparatus to a predetermined annealing temperature for predetermined annealing time in order to activate the p-type impurities of the p-type nitride semiconductor layer 5. In more details, this process aims to activate the p-type impurities of the p-type AlGaN layer 52 and the like. As to annealing conditions, the annealing temperature is set to be in a range of 600 to 850° C. and the annealing time is set to be in a range of 10 to 50 minutes, but these values are only examples and there is no intent to limit them by these values. Examples of the annealing apparatus may include lamp annealing apparatus, and electrical furnace and oven annealing apparatus.

(4) Process of Forming the Mesa Structure 22

This process includes forming a first resist layer on a region of the nitride semiconductor layer 20 corresponding to the upper face 22a of the mesa structure 22 (the surface 20a of the nitride semiconductor layer 20), by photolithography techniques. Further, this process includes forming the mesa structure 22 by etching partially the nitride semiconductor layer 20 from the surface 20a until reaching an almost middle of the n-type nitride semiconductor layer 3 while the first resist layer is used as a mask. Furthermore, this process includes removing the first resist layer. It is preferable that the nitride semiconductor layer 20 be etched with a dry etching system, for example. The dry etching system may preferably be an inductively coupled plasma etching system, for example.

(5) Process of Forming the Insulating Film 10

This process includes forming a silicon oxide film serving as a base for the insulating film 10, over a whole of the first plane of the wafer, by PECVD (plasma-enhanced chemical vapor deposition), for example. This process further includes forming the insulating film 10 by patterning the silicon oxide film on the first plane of the wafer so as to form the first contact hole 10b and the second contact hole 10a in the silicon oxide film. Note that, examples of methods of forming the silicon oxide film may include PECVD as well as other CVD, for example. Patterning of the silicon oxide film may be achieved by use of photolithography techniques and etching techniques.

(6) Process of Forming the First Contact Electrode 9

This process includes a first step of forming a second resist layer over the first plane of the wafer, the second resist layer being patterned to expose only a region where the first contact electrode 9 is to be formed, that is, exposed part of the surface 3a of the n-type nitride semiconductor layer 3. Further, this process includes a second step of forming, by evaporation, a laminated film on the surface 3a of the n-type nitride semiconductor layer 3, the laminated film including a first Al film, a first Ni film, a second Al film, a second Ni film, and an Au film which are laminated in this order from the surface 3a. Such evaporation may preferably be electron beam evaporation. Examples of methods of forming laminated films may include evaporation as well as sputtering. Furthermore, this process includes a third step of removing the second resist layer and unnecessary films on the second resist layer by lift off. Moreover, the process includes a fourth step of forming the first contact electrode 9 by annealing and slow cooling. Such annealing may preferably be RTA (rapid thermal annealing) under N₂ gas atmosphere.

Conditions for RTA treatment may include an annealing temperature of 650° C. and annealing time of 1 minute, for example. The annealing temperature may be preferably equal to or higher than an eutectic point of AlNi (640° C.) and be equal to or smaller than 700° C. The annealing temperature may be appropriately changed based on the Al composition ratio of the n-type nitride semiconductor layer 3. The annealing time may be preferably selected from a range of, for example, about 30 seconds to 3 minutes. The eutectic point means a temperature causing transformation of an eutectic mixture from a liquid phase to a solid phase while keeping its composition.

Slow cooling means a process of cooling gradually. A cooling speed for slow cooling may be 30° C./min, for example. The cooling speed is not limited to 30° C./min, but may be preferably selected from a range of, for example, 20 to 60° C./min appropriately.

In this process, the annealing may be preferably done by use of infrared annealing apparatus. The infrared annealing apparatus may include an infrared lamp serving as a heater, a quartz oven for accommodating a work, and a vacuum pump serving as a pressure adjuster for adjusting a pressure inside the oven. A preferable example of the infrared annealing apparatus may be a halogen lamp annealing apparatus including a halogen lamp as an infrared lamp. Note that, the work means a wafer-like structure in which the nitride semiconductor layer 20 having the mesa structure 22 is formed on the wafer and the laminated film is formed on the exposed surface 3a of the n-type nitride semiconductor layer 3. The halogen lamp annealing apparatus allows changing the cooling speed in slow cooling by adjusting a flow rate of an N₂ gas supplied to the oven.

The prevent inventors would submit the following putative comments on a mechanism in which the first contact electrode 9 is formed by annealing and slow cooling in this process. Note that, the method of manufacturing the semiconductor device 100 may be based on a different putative mechanism.

In this process, the laminated film is melted by annealing. In slow cooling, the Ni primary crystals 9a are precipitated first, and then eutectic structures of AlNi are solidified (the AlNi eutectic 9b is formed). According to this process, the first contact electrode 9 formed of a solidification structure containing Ni and Al as its main components can be formed. In more detail, according to this process, the first contact electrode 9 formed of a solidification structure containing the multiple Ni primary crystals 9a and the AlNi eutectic 9b can be formed. In this regard, the Ni primary crystal 9a contains Au as impurities. In more detail, the Ni primary crystal 9a contains a small amount (ppm level) of Au as impurities, but Ni occupies 99% or more of the Ni primary crystal 9a. The Ni primary crystal 9a does not grow isotopically (in other words, a growth speed varies depending on a direction), and therefore grows dendritically. Further, the AlNi eutectic 9b contains Au as impurities. The first contact electrode 9 is considered to have an impurity state due to formation of solid solution of Ni and N which is dissociated from the n-type nitride semiconductor layer 3 in annealing. Hence, it is considered to be possible to reduce the contact resistance with the n-type nitride semiconductor layer 3 due to tunnel effects. In other words, it would be considered that the first contact electrode 9 takes in some of nitrogen from the n-type nitride semiconductor layer 3 and this may result in ohmic contact between the n-type nitride semiconductor layer 3 and the first contact electrode 9. Therefore, the Ni primary crystal 9a contains N as impurities.

In annealing, with regard to the laminated film, it may be considered that the first and second Al films are melted first, and then the Ni film between the first and second Al films is melted, and subsequently the Ni film between the second Al film and the Au film is melted, and thereafter the Au film is melted. Therefore, the Au film can serve as a protective film for suppressing oxidation of Ni by oxygen in atmosphere before annealing and oxidation of Ni by residual oxygen in the oven. According to the method of manufacturing the semiconductor device 100, it is possible to suppress a rise in a melting point which would be otherwise caused by oxidation of Ni. In summary, according to the method of manufacturing the semiconductor device 100, it is possible to decrease the necessary anneal temperature in the process of forming the first contact electrode 9.

(7) Process of Forming the Second Contact Electrode 8

This process includes forming the second contact electrode 8 on the surface 5a of the p-type nitride semiconductor layer 5.

In more detail, this process includes forming a third resist layer over the first plane of the wafer, the third resist layer being patterned to expose only a region where the second contact electrode 8 is to be formed, that is, part of the surface 52a of the p-type AlGaN layer 52. Further, this process includes forming, by evaporation, a laminated film on the surface 5a of the p-type nitride semiconductor layer 5, the laminated film including an Al film, an Ni film, and an Au film which are laminated in this order from the surface Sa, for example. Furthermore, this process includes removing the third resist layer and unnecessary films on the third resist layer by lift off. Moreover, the process includes annealing and slow cooling to achieve ohmic contact between the second contact electrode 8 and the p-type nitride semiconductor layer 5.

(8) Process of Forming the First Extended Wire 29 and the Second Extended Wire 28

This process includes forming a fourth resist layer over the first plane of the wafer, the fourth resist layer being patterned to expose only individual regions where the first extended wire 29 and the second extended wire 28 are to be formed. Further, this process includes forming, by electron beam evaporation, a laminated film of a Ti layer and an Au layer, for example. Furthermore, this process includes removing the fourth resist layer and unnecessary films on the fourth resist layer by lift off. According to this process, the first extended wire 29 and the second extended wire 28 can be formed.

(9) Process of Forming the First Pad Electrode 19 and the Second Pad Electrodes 18

This process includes forming the first pad electrode 19 and the second pad electrodes 18 by use of photolithography techniques and thin film formation techniques, for example. Examples of thin film formation techniques may include evaporation. Such evaporation may preferably be electron beam evaporation.

(10) Process of Forming the Adhesive Layers 14

This process includes forming a fifth resist layer over the first plane of the wafer, the fifth resist layer being patterned to expose only individual regions where the adhesive layers 14 are to be formed. Further, this process includes forming, by electron beam evaporation, a Ti film with a thickness of 20 nm, for example. Furthermore, this process includes removing the fifth resist layer and unnecessary film(s) on the fifth resist layer by lift off. According to this process, the adhesive layers 14 can be formed. In this process, for example, any of a Cr film, an Nb film, a Zr film, a TiN film, and a TaN film can be formed instead of the Ti film.

(11) Process of Forming the Passivation Film 11

This process includes forming a silicon nitride film serving as a base for the passivation film 11 over a whole of the first plane of the wafer, by plasma CVD, for example. Further, this process includes forming the passivation film 11 by patterning the silicon nitride film over the first plane of the wafer so that the first opening 13 and the second openings 12 are formed in the silicon nitride film. Note that, examples of methods of forming the silicon nitride film may include plasma CVD as well as, for example, other CVD. Patterning of the silicon nitride film may be done by use of photolithography techniques and etching techniques.

(12) Process of Forming the Heat Dissipation Layer 60

This process includes forming a sixth resist layer over the first plane of the wafer, the sixth resist layer being patterned to expose only a region where the heat dissipation layer 60 is to be formed. Further, this process includes forming, by electron beam evaporation, a laminated film of a Ti film with a thickness of 20 nm and an Au film with a thickness of 1250 nm, for example. Furthermore, this process includes removing the sixth resist layer and unnecessary films on the sixth resist layer by lift off. According to this process, it is possible to form the heat dissipation layer 60 which has a multilayered structure of the first layer 61 formed of the Ti film (Ti layer) and the second layer 62 formed of the Au film (Au layer). In this process, for example, any of a Cr film, an Nb film, a Zr film, a TiN film, and a TaN film can be formed instead of the Ti film.

(13) Process of Forming Separation Grooves

This process includes forming separation grooves which extend from the surface 11a of the passivation film 11 over the wafer to reach an almost middle of the wafer in a thickness direction thereof. In this process, the separation grooves can be preferably formed by ablation processing with a laser processing machine. The ablation processing means laser processing under irradiation conditions which cause ablation.

(14) Process of Polishing the Wafer

This process includes thinning the wafer until the wafer has a thickness corresponding to a predetermined thickness of the substrate 1, by polishing a second plane which is an opposite plane of the wafer from the first plane. In polishing the wafer, a grinding process and a lapping process may be preferably performed sequentially, for example.

In the method of manufacturing the semiconductor device 100, by finishing this process, the wafer provided with the multiple semiconductor devices 100 can be completed. In summary, according to the method of manufacturing the semiconductor device 100, by performing the aforementioned processes (1) to (14) sequentially, the wafer provided with the multiple semiconductor devices 100 can be completed.

(15) Process of Dividing the Wafer Provided with the Multiple Semiconductor Devices 100 into the Separate Semiconductor Devices 100

This process is a dicing process, and includes dividing the wafer provided with the multiple semiconductor devices 100 into the separate semiconductor devices 100, by cutting it with a dicing saw or the like.

According to the method of manufacturing the semiconductor device 100 of the present embodiment as described above, it is possible to relatively easily manufacture the semiconductor device 100 with improved moisture resistance and improved heat radiation performance. Further, according to the method of manufacturing the semiconductor device 100 of the present embodiment, it is possible to relatively easily manufacture the semiconductor device 100 having a reduced contact resistance between the n-type nitride semiconductor layer 3 and the first contact electrode 9. Hereinafter, first of all, a decrease in the contact resistance between the n-type nitride semiconductor layer 3 and the first contact electrode 9 is described, and then the moisture resistance and the heat radiation performance are described.

As to the method of manufacturing the semiconductor device 100, when the mesa structure 22 is formed by etching, the surface 3a of the n-type nitride semiconductor layer 3 becomes uneven. In other words, the surface 3a of the n-type nitride semiconductor layer 3 has a structure in which protrusions and recesses are randomly present. For this reason, when the laminated film (multilayer film) for forming the first contact electrode 9 is merely formed by evaporation or the like, physical contact between the laminated film and the surface 3a of the n-type nitride semiconductor layer 3 may be considered to become insufficient. Hence, when the laminated film for forming the first contact electrode 9 is annealed at a temperature not causing melt of the laminated film, it is considered to be difficult to reduce the contact resistance between the first contact electrode 9 and the n-type nitride semiconductor layer 3. However, the method of manufacturing the semiconductor device 100 of the present embodiment includes melting the laminated film first and then precipitating the Ni primary crystals 9a to cause solidification of AlNi eutectic. Therefore, the first contact electrode 9 and the surface 3a of the n-type nitride semiconductor layer 3 can be made to be in contact with each other without clearances therebetween. According to the method of manufacturing the semiconductor device 100 of the present embodiment, a reaction of Ni with N in the n-type nitride semiconductor layer 3 can be facilitated, and consequently, the contact resistance can be reduced.

Additionally, Ni has a higher work function than Ti, and therefore the contact resistance becomes higher in a case where Ni is in simple contact with the n-type nitride semiconductor layer 3 than in a case where Al is in simple contact with the n-type nitride semiconductor layer 3. However, according to the method of manufacturing the semiconductor device 100 of the present embodiment, the laminated film is melted and thereby Ni reacts with N in the n-type nitride semiconductor layer 3 to form a solid solution with N. Consequently, the contact resistance can be reduced.

Moreover, AlNi eutectic has an eutectic point about 20° C. lower than that of AlTi eutectic, and thus a change in a melting point caused by deviation of the actual Al composition ratio from the Al composition ratio in eutectic composition is relatively small. Hence, the method of manufacturing the semiconductor device 100 of the present embodiment can suppress differences between electric properties of the first contact electrodes 9 of the semiconductor devices 100 of different lots, and reduce production cost.

Furthermore, according to the method of manufacturing the semiconductor device 100 of the present embodiment, it is possible to realize the first contact electrode 9 of which the multiple Ni primary crystals 9a include an Ni primary crystal 9aa (see FIG. 9) which satisfies the following requirement.

Requirement: extending an entire length in the thickness direction of the first contact electrode 9, and having a continuous region in contact with the n-type nitride semiconductor layer 3 which has a dimension W1 (see FIG. 9) in a direction in a plane of the first contact electrode 9 larger than a thickness H1 (see FIG. 9) of the first contact electrode 9.

To form the first contact electrode 9 on the surface 3a of the n-type nitride semiconductor layer 3, the laminated film is formed on the surface 3a of the n-type nitride semiconductor layer 3. In the laminated film, the Al film and the Ni film are stacked alternately, and the Au film is formed on the uppermost Ni film. Thereafter, in the method of manufacturing the semiconductor device 100 of the present embodiment, the laminated film is melted by annealing at an annealing temperature equal to or higher than 640° C. and equal to or lower than 700° C. and slow cooling to form the first contact electrode 9. Thus, according to the method of manufacturing the semiconductor device 100 of the present embodiment, it is possible to form the first contact electrode 9 having a solidification structure containing Ni and Al as its main components. According to the method of manufacturing the semiconductor device 100 of the present embodiment, it is possible to manufacture the semiconductor device 100 capable of reducing the contact resistance between the n-type nitride semiconductor layer 3 and the first contact electrode 9. The number of stacked structures of the Al film and the Ni film in the laminated film may be two or more, and optional.

In the method of manufacturing the semiconductor device 100, the cooling speed in slow cooling may preferably be in a range of 20 to 60° C./min. According to the method of manufacturing the semiconductor device 100, it is possible to form a solidification structure containing a mixture of the multiple Ni primary crystals 9a and the AlNi eutectic 9b which are in contact with the surface 3a of the n-type nitride semiconductor layer 3. As for the method of manufacturing the semiconductor device 100, when the cooling rate is lower than 20° C./min, the Ni primary crystals 9a tend to be smaller in size, and this may lead to decrease in contact areas between the Ni primary crystals 9a and the surface 3a of the n-type nitride semiconductor layer 3. Hence, in the method of manufacturing the semiconductor device 100, in consideration of decreasing the contact resistance, the cooling rate may be preferably equal to or higher than 20° C./min. In the method of manufacturing the semiconductor device 100, when the cooling rate is equal to or higher than 60° C./min, a solidification structure containing a mixture of the multiple Ni primary crystals 9a and the AlNi eutectic 9b is unlikely to form, and the laminated film tends to become amorphous. Hence, in the method of manufacturing the semiconductor device 100, in consideration of decreasing the contact resistance, the cooling rate may be preferably equal to or higher than 20° C./min and equal to or lower than 60° C./min.

The first contact electrode 9 is made of a solidification structure containing Ni and Al as its main components, as described above. Accordingly, the semiconductor device 100 can have the contact resistance between the n-type nitride semiconductor layer 3 and the first contact electrode 9 reduced. The contact resistance can be measured by, for example, TLM (transfer length method). Measurement of the contact resistance by TLM can be conducted by use of evaluation samples with, for example, a semiconductor parameter analyzer (for example, product name: HP4155A available from Hewlett Packard Company). The evaluation samples are prepared by forming multiple evaluation electrodes in conformity with the same specifications as the first contact electrode 9 on the surface 3a of the n-type nitride semiconductor layer 3. The specifications specify materials and thicknesses.

Note that, Document 2 [WO 2012/039442 A1] shows measurement results of relationships between contact resistances between n electrodes (Ti/Al/Ti/Au) formed on n-type AlₓGa₁₋ₓN layers and the n-type AlₓGa₁₋ₓN layers and thermal treatment temperatures. Document 2 shows measurement results of such relationships with regard to four conditions of AlN mole fraction “x” of 0, 0.25, 0.4, and 0.6 of the n-type AlₓGa₁₋ₓN layer. Document 2 teaches that thermal treatment at a higher temperature is required as a light emission wavelength becomes shorter, that is, the AlN mole fraction “x” becomes greater. Document 2 discloses that the contact resistance has a minimum value when the thermal treatment temperature is about 950° C. in a case where the AlN mole fraction “x” is 0.6, and that the minimum value of the contact resistance is about 1×10⁻² Ωcm². In contrast, according to the semiconductor device 100, the contact resistance between the n-type nitride semiconductor layer 3 formed of the n-type Al_{0.7}Ga_{0.3}N layer with the higher Al composition ratio and the first contact electrode 9 can be set to about 5×10⁻³ Ωcm². Note that, in the semiconductor device 100, the contact resistance tends to increase with an increase in the Al composition ratio.

Note that, in a stage of research of developing the semiconductor device 100 with the improved moisture resistance, the present inventors evaluated the moisture resistance of a semiconductor device of a first example. The semiconductor device of the first example is an ultraviolet light emitting diode having the first pad electrode 19 directly formed on the first contact electrode 9 and the second pad electrodes 18 directly formed on the second contact electrode 8 in the substantially same manner as the semiconductor device 100. Additionally, the semiconductor device of the first example includes the p-type nitride semiconductor layer 5 as in the semiconductor device 100, which has a stacked structure of a first p-type AlGaN layer, a second p-type AlGaN layer, and a p-type GaN layer and an uppermost layer of the p-type nitride semiconductor layer 5 is formed of the p-type GaN layer. Further, the semiconductor device of the first example includes the second contact electrode 8 as in the semiconductor device 100, which is formed by forming the laminated film of an Ni film with a thickness of 30 nm and an Au film with a thickness of 200 nm on the surface 5a of the p-type nitride semiconductor layer 5 and then annealing the same. Furthermore, the semiconductor device of the first example does not include a component corresponding to the heat dissipation layer 60 of the semiconductor device 100.

First, to evaluate the moisture resistance of the semiconductor device of the first example, the present inventors conducted a high temperature and high humidity electrical current test to evaluate electrical properties and check appearance with an optical microscope and an SEM (scanning electron microscope), for example. In the high temperature and high humidity electrical current test, the temperature is 60° C., the relative humidity is 80 RH %, the flowing current is 20 mA, and the continuous conduction time is 2000 hours. As a result, the present inventors found that it was necessary to improve the moisture resistance of the semiconductor device of the first example. In more detail, the present inventors found that in some cases defects occurred in the semiconductor device of the first example in a process of the high temperature and high humidity electrical current test. Examples of the defects may include an open failure, corrosion of a region of the AlGaN layer 31 beneath the first contact electrode 9, breakage of the periphery of the first pad electrode 19, and breakage of part of the passivation film 11 on broken part of the periphery of the first pad electrode 19. The corrosion of a region of the AlGaN layer 31 beneath the first contact electrode 9 means oxidation of a region of the AlGaN layer 31 beneath the first contact electrode 9, and also means formation of Al₂O₃.

Additionally, the present inventors found that in the semiconductor device of the first example defects such as corrosion of the p-type GaN layer and breakage of the periphery of the second pad electrode 18 did not occur even when the aforementioned defects occurred.

The prevent inventors would submit the following putative comments on a mechanism in which the aforementioned defects occur in the semiconductor device of the first example.

In the semiconductor device of the first example, moisture intrudes therein through defects such as pinholes or cracks in the passivation film 11 and reaches the surface 31a of the AlGaN layer 31 by way of defects such as crystal grain boundaries, pinholes, and cracks of the Au layer forming the first pad electrode 19. In such a case, in the semiconductor device of the first example, when a flow of current causes holes (h⁺) inside the AlGaN layer 31, the following electrochemical reaction may occur near the surface 31a of the AlGaN layer 31 due to presence of AlN in the AlGaN layer 31.

2AlN+6h⁺→2Al³⁺+N₂

2Al³⁺+6OH⁻→Al₂O₃+3H₂O

In summary, in the semiconductor device of the first example, N₂ may be produced near the surface 31a of the AlGaN layer 31, and oxidation reaction may cause formation of Al₂O₃ resulting in electrically insulating and volume expansion. For this reason, the semiconductor device of the first example may suffer from defects such as corrosion of the region of the AlGaN layer 31 beneath the first contact electrode 9, breakage of the periphery of the first pad electrode 19, and breakage of part of the passivation film 11 on broken part of the periphery of the first pad electrode 19. Further, in the semiconductor device of the first example, a current path in the AlGaN layer 31 may be changed due to formation of Al₂O₃. Thus, an electrically insulating region may expand, and thus the region of the AlGaN layer 31 beneath the first contact electrode 9 may also be included in the electrically insulating region, which may cause an open failure preventing a flow of current.

In contrast, a path necessary for moisture to reach the surface 31a of the AlGaN layer 31 becomes longer in the semiconductor device 100 than in the semiconductor device of the first example, and thus the moisture resistance can be improved.

The semiconductor device 100 of the present embodiment includes the AlGaN layers 31 and 52, and the contact electrodes 9 and 8 formed on the surfaces 31a and 52a of the AlGaN layers 31 and 52 respectively. Further, the semiconductor device 100 includes the insulating film 10 formed on the surfaces 31a and 52a of the AlGaN layers 31 and 52 to surround regions of the contact electrodes 9 and 8 in contact with the AlGaN layers 31 and 52 respectively, and the passivation film 11. The semiconductor device 100 further includes the extended wires 29 and 28 electrically connected to the contact electrodes 9 and 8 and extending over the contact electrodes 9 and 8 and the insulating film 10 respectively. Further, the semiconductor device 100 includes the pad electrodes 19 and 18 formed on parts of the extended wires 29 and 28 formed on the insulating film 10 and electrically connected to the extended wires 29 and 28 respectively. The passivation film 11 covers the insulating film 10 and the extended wires 29 and 28 and includes the openings 13 and 12 for exposing the pad electrodes 19 and 18 respectively. The insulating film 10 accommodates the openings 13 and 12 in a plan view. The passivation film 11 accommodates the contact electrodes 9 and 8 in a plan view. The semiconductor device 100 further includes the heat dissipation layer 60 which is formed on the surface 11a of the passivation film 11 and made of material having a higher heat conductivity than material of the passivation film 11. According to the semiconductor device 100 described above, the moisture resistance can be improved and the heat radiation performance also can be improved. Therefore, the semiconductor device 100 can improve light output as well as improve reliability.

In a preferable aspect of the semiconductor device 100, the AlGaN layers 31 and 52 include the n-type AlGaN layer 31 and the p-type AlGaN layer 52. The p-type AlGaN layer 52 is smaller than the n-type AlGaN layer 31 in a plan view. In other words, the p-type AlGaN layer 52 and the n-type AlGaN layer 31 overlap with each other in the thickness direction of the n-type AlGaN layer 31, and a planar size of the p-type AlGaN layer 52 is smaller than a planar size of the n-type AlGaN layer 31. In brief, the p-type AlGaN layer 52 is positioned inside the n-type AlGaN layer 31 not to extend across an outer limit of the n-type AlGaN layer 31 in a plan view. In the semiconductor device 100, the contact electrodes 9 and 8 include the first contact electrode 9 formed on the exposed surface 31a of the n-type AlGaN layer 31 and the second contact electrode 8 formed on the surface 52a of the p-type AlGaN layer 52. In the semiconductor device 100, the extended wires 29 and 28 include the first extended wire 29 electrically connected to the first contact electrode 9 and the second extended wire 28 electrically connected to the second contact electrode 8. In the semiconductor device 100, the pad electrodes 19 and 18 include the first pad electrode 19 electrically connected to the first extended wire 29 and the second pad electrodes 18 electrically connected to the second extended wire 28. Accordingly, the semiconductor device 100 can have the emission wavelength of the ultraviolet light emitting device shortened, as well as have the moisture resistance improved.

In this semiconductor device 100, the light emitting layer 4 with the emission wavelength falling within the wavelength range of ultraviolet may be preferably provided between the n-type the AlGaN layer 31 and the p-type AlGaN layer 52. In this case, the semiconductor device 100 can have light emission efficiency of the ultraviolet light emitting device improved.

In this semiconductor device 100, the AlGaN layers 31 and 52 each may be preferably an AlₓGa₁₋ₓN (0.4<x<1) layer. In this case, the semiconductor device 100 can have the emission wavelength of the ultraviolet light emitting device set to a wavelength range of UV-C.

In the semiconductor device 100, the heat dissipation layer 60 may preferably include the first layer 61 formed on the surface 11a of the passivation film 11 and the second layer 62 formed on the first layer 61, the passivation film 11 may include a silicon nitride film, the second layer 62 may be of an Au layer, and the first layer 61 may be made of material which is one selected from a group consisting of Ti, Cr, Nb. Zr, TiN and TaN. The semiconductor device 100 can have the moisture resistance improved in contrast to a case of the passivation film 11 being a silicon oxide film, and can have adhesion between the heat dissipation layer 60 and the passivation film 11 in contrast to a case of the heat dissipation layer 60 being a single Au layer.

In this semiconductor device 100, the insulating film 10 may be preferably a silicon oxide film. In this case, the semiconductor device 100 can have the insulating film 10 improved in density.

Additionally, the semiconductor device 100 includes the first extended wire 29 beneath the first pad electrode 19, and thereby can reduce, by the presence of the first extended wire 29, impact which may occur when bonding bumps or wires to the first pad electrode 19. Moreover, the semiconductor device 100 includes the second extended wire 28 beneath the second pad electrodes 18, and thereby can reduce, by the presence of the second extended wire 28, impact which may occur when bonding bumps or wires to the second pad electrode 18. Accordingly, the semiconductor device 100 can suppress occurrence of cracks in the first pad electrode 19 and the second pad electrodes 18.

Further, in the semiconductor device 100, the passivation film 11 may preferably cover the insulating film 10, the first extended wire 29, the second extended wire 28, the periphery of the first pad electrode 19, and the peripheries of the second pad electrodes 18. Accordingly, the semiconductor device 100 can have the moisture resistance further improved. Furthermore, the semiconductor device 100 may preferably include an adhesive layer 14 between the passivation film 11 and the periphery of the first pad electrode 19, and other adhesive layers 14 between the passivation film 11 and the peripheries of the second pad electrodes 18. Accordingly, the semiconductor device 100 can have the moisture resistance further improved.

The ultraviolet light emitting device of the present embodiment described above includes the substrate 1, and the nitride semiconductor layer 20 which is formed facing the first face (main surface) 1a and includes the n-type nitride semiconductor layer 3, the light emitting layer 4, and the p-type nitride semiconductor layer 5 arranged in this order from the first face 1a. Further, the ultraviolet light emitting device includes the first contact electrode 9 formed on the exposed surface 31a of the n-type AlGaN layer 31 of the n-type nitride semiconductor layer 3, and the second contact electrode 8 formed on the surface 52a of the p-type AlGaN layer 52 of the p-type nitride semiconductor layer 5. Furthermore, the ultraviolet light emitting device includes the insulating film 10 and the passivation film 11. The insulating film 10 is formed on the surface 31a of the n-type AlGaN layer 31 to surround the region of the first contact electrode 9 in contact with the n-type AlGaN layer 31, and also is formed on the surface 52a of the p-type AlGaN layer 52 to surround the region of the second contact electrode 8 in contact with the p-type AlGaN layer 52. Additionally, the ultraviolet light emitting device includes the first extended wire 29 electrically connected to the first contact electrode 9 and extending over the first contact electrode 9 and the insulating film 10. Moreover, the ultraviolet light emitting device includes the first pad electrode 19 which is formed on part of the first extended wire 29 formed on the insulating film 10 and are electrically connected to the first extended wire 29. In addition, the ultraviolet light emitting device includes the second extended wire 28 electrically connected to the second contact electrode 8 and extending over the second contact electrode 8 and the insulating film 10. Further, the ultraviolet light emitting device includes the second pad electrodes 18 which are formed on part of the second extended wire 28 formed on the insulating film 10 and are electrically connected to the second extended wire 28. The passivation film 11 covers the insulating film 10, the first extended wire 29, and the second extended wire 28, and includes the first opening 13 for exposing the first pad electrode 19 and the second openings 12 for exposing the second pad electrodes 18. The insulating film 10 accommodates the first opening 13 and the second openings 12 in a plan view. The passivation film 11 accommodates the first contact electrode 9 and the second contact electrode 8 in a plan view. The ultraviolet light emitting device includes the heat dissipation layer 60 which is formed on the surface 11a of the passivation film 11 and made of material having a higher heat conductivity than material of the passivation film 11. The ultraviolet light emitting device including the above configuration can improve the moisture resistance as well as improve the heat radiation performance.

Such a semiconductor device may not be limited to an ultraviolet light emitting device, but may be GaN-based HEMT (high electron mobility transistor), for example. The GaN-based HEMT has a heterojunction given by a GaN layer and an AlGaN layer, and has a drain electrode, a source electrode, and a gate insulating film formed on a surface of the AlGaN layer, and has a gate electrode formed on the gate insulating film. In the HEMT corresponding to a semiconductor device of one aspect according to the present invention, part of the aforementioned insulating film 10 can serve as the gate insulating film, and arrangement of the aforementioned contact electrodes can be applied to the drain electrode and the source electrode.

(Aspects According to the Present Invention)

As apparent from the above embodiment, the semiconductor device (100) of the first aspect according to the present invention includes: an AlGaN layer (31, 52); a contact electrode (9, 8) formed on a surface (31a, 52a) of the AlGaN layer (31, 52); an insulating film (10) formed on the surface (31a, 52a) of the AlGaN layer (31, 52) to surround a region of the contact electrode (9, 8) in contact with the AlGaN layer (31, 52); and a passivation film (11). The semiconductor device (100) further includes: an extended wire (29, 28) electrically connected to the contact electrode (9, 8) and extending over the contact electrode (9, 8) and the insulating film (10); and a pad electrode (19, 18) formed on part of the extended wire (29, 28) formed on the insulating film (10) and electrically connected to the extended wire (29, 28). The passivation film (11) covers the insulating film (10) and the extended wire (29, 28) and including an opening (13, 12) for exposing the pad electrode (19, 18). The insulating film (10) accommodates the opening (13, 12) in a plan view. The passivation film (11) accommodates the contact electrode (9, 8) in a plan view. The semiconductor device (100) further includes a heat dissipation layer (60) which is formed on a surface (11a) of the passivation film (11) and made of material having a higher heat conductivity than material of the passivation film (11).

In the semiconductor device (100) of the second aspect according to the present invention which would be realized in combination with the first aspect, the AlGaN layer (31, 52) includes an n-type AlGaN layer (31) and a p-type AlGaN layer (52). The p-type AlGaN layer (52) is smaller than the n-type AlGaN layer (31) in a plan view. The contact electrode (9, 8) includes a first contact electrode (9) formed on an exposed surface (31a) of the n-type AlGaN layer (31) and a second contact electrode (8) formed on a surface (52a) of the p-type AlGaN layer (52). The extended wire (29, 28) includes a first extended wire (29) electrically connected to the first contact electrode (9) and a second extended wire (28) electrically connected to the second contact electrode (8). The pad electrode (19, 18) includes a first pad electrode (19) electrically connected to the first extended wire (29) and a second pad electrode (18) electrically connected to the second extended wire (28).

The semiconductor device (100) of the third aspect according to the present invention which would be realized in combination with the second aspect, further includes a light emitting layer (4) between the n-type AlGaN layer (31) and the p-type AlGaN layer (52). The light emitting layer (4) is configured to emit light with an emission wavelength falling within a wavelength range of ultraviolet.

In the semiconductor device (100) of the fourth aspect according to the present invention which would be realized in combination with the second or third aspect, the AlGaN layer (31, 52) includes an AlₓGa₁₋ₓN layer where x is larger than 0.4 and smaller than 1.

In the semiconductor device (100) of the fifth aspect according to the present invention which would be realized in combination with any one of the first to fourth aspects, the heat dissipation layer (60) includes a first layer (61) formed on the surface (11a) of the passivation film (11) and a second layer (62) formed on the first layer (61). The passivation film (11) includes a silicon nitride film. The second layer (62) is of an Au layer. The first layer (61) is made of material which is one selected from a group consisting of Ti, Cr, Nb, Zr, TiN and TaN.

In the semiconductor device (100) of the sixth aspect according to the present invention which would be realized in combination with any one of the first to fifth aspects, the insulating film (10) includes a silicon oxide film.

1. A semiconductor device comprising:
an AlGaN layer;
a contact electrode formed on a surface of the AlGaN layer;
an insulating film formed on the surface of the AlGaN layer to surround a region of the contact electrode in contact with the AlGaN layer; and
a passivation film,
the semiconductor device further comprising:
an extended wire electrically connected to the contact electrode and extending over the contact electrode and the insulating film; and
a pad electrode formed on part of the extended wire formed on the insulating film and electrically connected to the extended wire,
the AlGaN layer including an n-type AlGaN layer, and a p-type AlGaN layer,
the p-type AlGaN layer being smaller than the n-type AlGaN layer in a plan view,
the contact electrode including a first contact electrode formed on an exposed surface of the n-type AlGaN layer, and a second contact electrode formed on a surface of the p-type AlGaN layer,
the extended wire including a first extended wire electrically connected to the first contact electrode, and a second extended wire electrically connected to the second contact electrode,
the pad electrode including a first pad electrode electrically connected to the first extended wire, and a second pad electrode electrically connected to the second extended wire,
the semiconductor device further comprising a light emitting layer between the n-type AlGaN layer and the p-type AlGaN layer,
the light emitting layer being configured to emit light with an emission wavelength falling within a wavelength range of ultraviolet,
the passivation film covering the insulating film and the extended wire and including an opening for exposing the pad electrode,
the insulating film accommodating the opening in a plan view,
the passivation film accommodating the contact electrode in a plan view, and
the semiconductor device further comprising a heat dissipation layer which is formed on a surface of the passivation film and made of material having a higher heat conductivity than material of the passivation film.

2. (canceled)

3. (canceled)

4. The semiconductor device of claim 1, wherein
the AlGaN layer includes an AlₓGa₁₋ₓN layer where x is larger than 0.4 and smaller than 1.

5. The semiconductor device of claim 1, wherein:
the heat dissipation layer includes a first layer formed on the surface of the passivation film and a second layer formed on the first layer;
the passivation film includes a silicon nitride film;
the second layer is of an Au layer; and
the first layer is made of material which is one selected from a group consisting of Ti, Cr, Nb, Zr, TiN and TaN.

6. The semiconductor device of claim 1,
the insulating film includes a silicon oxide film.
